(19) United States
(12) Patent Application Publication
(10) Pub. No.: US 2016/0164487 A1
(43) Pub. Date: Jun. 9, 2016

(54) BULK ACOUSTIC WAVE FILTER

(71) Applicant: Samsung Electro-Mechanics Co., Ltd., Suwon-si (KR)

(72) Inventors: Jea Shik SHIN, Suwon-si (KR); Moon Chul LEE, Suwon-si (KR); Chul Soo KIM, Suwon-si (KR)

(73) Assignee: Samsung Electro-Mechanics Co., Ltd., Suwon-si (KR)

(21) Appl. No.: 14/885,604

(22) Filed: Oct. 16, 2015

(30) Foreign Application Priority Data
Dec. 5, 2014 (KR) 10-2014-0173808

(51) Int. Cl. H03H 9/58; H03H 9/02; H03H 9/205

(52) U.S. Cl. CPC H03H 9/02007; H03H 9/205

(57) ABSTRACT

A bulk acoustic wave filter may include: a first resonator part including one or more first bulk acoustic wave resonators connected between a signal port for transmitting or receiving a signal and a node connected to an antenna port; and a second resonator part including one or more second bulk acoustic wave resonators connected between the signal port and a ground, wherein a quality factor (IF) value of the one or more first bulk acoustic wave resonators is less than a IF value of the one or more second bulk acoustic wave resonators.

### CROSS-REFERENCE TO RELATED APPLICATION(S)

This application claims the benefit of Korean Patent Application No. 10-2014-0173808 filed on Dec. 5, 2014, in the Korean Intellectual Property Office, the entire disclosure of which is incorporated herein by reference for all purposes.

### BACKGROUND

1. Field

The following description relates to a bulk acoustic wave filter.

2. Description of Related Art

Recently, in order to efficiently use limited frequency bands, a band gap between used frequency bands has been decreased. In order to decrease interference between the frequency bands caused by the deceased band gap, a bulk acoustic wave filter having an increased quality factor (IF) has been widely used.

In addition, in order to increase data transmission amounts and data transfer rates, bulk acoustic wave resonators are required to have broad bandwidths. To this end, an electro-mechanical coupling coefficient (kt2) value of such bulk acoustic wave filters must be increased.

In general, the IF and kt2 values of a bulk acoustic wave filter may have a conflicting relationship. For example, when the IF value of the bulk acoustic wave filter is increased, the kt2 value of the bulk acoustic wave filter may be decreased. In addition, as the kt2 value of the bulk acoustic wave filter is lowered, a ripple may occur in the output of the bulk acoustic wave filter. Thus, technology capable of reducing the ripple occurring in the output of the bulk acoustic wave filter and widening bandwidth is desirable.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a bulk acoustic wave filter may include: a first resonator part including one or more first bulk acoustic wave resonators connected between a signal port for transmitting or receiving a signal and a node connected to an antenna port; and a second resonator part including one or more second bulk acoustic wave resonators connected between the signal port and a ground, wherein a quality factor (IF) value of the one or more first bulk acoustic wave resonators is less than a IF value of the one or more second bulk acoustic wave resonators.

The one or more first bulk acoustic wave resonators may include a first plurality of bulk acoustic wave resonators connected in series with each other, and the one or more second bulk acoustic wave resonators may include a second plurality of bulk acoustic wave resonators connected in parallel with each other.

The first plurality of bulk acoustic wave resonators and the second plurality of bulk acoustic wave resonators may each include: a piezoelectric layer including a piezoelectric material; electrodes disposed on opposing surfaces of the piezoelectric layer, and a frame disposed on one of the opposing surfaces of the piezoelectric layer and surrounding at least one of the electrodes. A width of the frame included in at least one bulk acoustic resonator among the first plurality of bulk acoustic wave resonators may be narrower than a width of the frame included in at least one bulk acoustic wave resonator among the second plurality of bulk acoustic wave resonators.

Each of the one or more first bulk acoustic wave resonators and each of the one or more second bulk acoustic wave resonators may include a piezoelectric layer including a piezoelectric material, electrodes disposed on opposing surfaces of the piezoelectric layer, and a frame disposed on one of the opposing surfaces of the piezoelectric layer and surrounding at least one of the electrodes. A width of the frame included in the at least one bulk acoustic wave resonator among the one or more first bulk acoustic wave resonators may be narrower than a width of the frame included in the one or more second bulk acoustic wave resonators.

An electro-mechanical coupling coefficient (kt2) value of the one or more first bulk acoustic wave resonators may be greater than a kt2 value of the one or more second bulk acoustic wave resonators.

According to another general aspect, a bulk acoustic wave filter may include: a first resonator part including one or more first bulk acoustic wave resonators connected to a node connected to an antenna port; a second resonator part including one or more second bulk acoustic wave resonators connected between the first resonator part and a ground; a third resonator part including one or more third bulk acoustic wave resonators connected between the second resonator part and a signal port for transmitting or receiving a signal; and a fourth resonator part including one or more fourth bulk acoustic wave resonators connected between the third resonator part and the ground. An electro-mechanical coupling coefficient (kt2) value of at least one bulk acoustic resonator, among the one or more first bulk acoustic wave resonators and the one or more third bulk acoustic wave resonators, may be greater than a kt2 value of the one or more second bulk acoustic wave resonators and a kt2 value of the one or more fourth bulk acoustic wave resonators.

At least one of the one or more first bulk acoustic wave resonators and the one or more third bulk acoustic wave resonators may include a first plurality of bulk acoustic wave resonators connected in series with each other, and at least one of the one or more second bulk acoustic wave resonators and the one or more fourth bulk acoustic wave resonators may include a second plurality of bulk acoustic wave resonators connected in parallel with each other.

The first plurality of bulk acoustic wave resonators and the second plurality of bulk acoustic wave resonators may each include a piezoelectric layer including a piezoelectric material, electrodes disposed on opposing surfaces of the piezoelectric layer, and a frame disposed on one of the opposing surfaces of the piezoelectric layer and surrounding at least one of the electrodes. A width of the frame included in at least one bulk acoustic wave resonator among the first plurality of bulk acoustic wave resonators may be narrower than a width of the frame included in at least one bulk acoustic wave resonator among the second plurality of bulk acoustic wave resonators.

Each of the one or more first bulk acoustic wave resonators, the one or more second bulk acoustic wave resonators, the one or more third bulk acoustic wave resonators, and the one or more fourth bulk acoustic wave resonators may include a piezoelectric layer including a piezoelectric material, electrodes disposed on opposing surfaces of the piezoelectric layer, and a frame disposed on one of the opposing surfaces of the piezoelectric layer and surrounding at least one of the electrodes. A width of the frame included in at least one of the one or more first bulk acoustic wave resonators and the one or more third bulk acoustic wave resonators may be narrower than a width of the frame included in the one or more second bulk acoustic wave resonators and a width of the frame included in the one or more fourth bulk acoustic wave resonators.

A quality factor (IF) value of at least one bulk acoustic wave resonator among the one or more first bulk acoustic wave resonators and the one or more third bulk acoustic wave resonators may be less than a IF value of the one or more second bulk acoustic wave resonators and a IF value of the one or more fourth bulk acoustic wave resonators.

According to another general aspect, a bulk acoustic wave filter may include: first bulk acoustic wave resonators connected in series with each other; and second bulk acoustic wave resonators connected in parallel with each other, and connected to the first bulk acoustic wave resonators. Each of the first bulk acoustic wave resonators and each of the second bulk acoustic wave resonators may include a piezoelectric layer including a piezoelectric material, electrodes disposed on opposing surfaces of the piezoelectric layer, and a frame disposed on one of the opposing surfaces of the piezoelectric layer and surrounding at least one of the electrodes. The frame of at least one first bulk acoustic wave resonator among the first bulk acoustic wave resonators may have a width that is narrower than a width of a frame of at least one second bulk acoustic wave resonator among the second bulk acoustic wave resonators.

The frame of the at least one first bulk acoustic wave resonator may provide the at least one first bulk acoustic wave resonator with a quality factor (IF) value that is less than a IF value of the at least one second bulk acoustic wave resonator.

Other features and aspects will be apparent from the following detailed description, the drawings, and the claims.

### BRIEF DESCRIPTION OF DRAWINGS

FIGS. 1 through 4 are diagrams illustrating examples of bulk acoustic wave filters.

FIG. 5 is a diagram illustrating an example of a bulk acoustic wave resonator included in a bulk acoustic wave filter.

FIGS. 6A and 6B are Smith charts illustrating example frequency characteristics of the bulk acoustic wave resonator having a frame of a wide width, with FIG. 6B showing an enlarged portion A of FIG. 6A.

FIGS. 7A and 7B are Smith charts illustrating example frequency characteristics of the bulk acoustic wave resonator having the frame of a narrow width, with FIG. 7B showing an enlarged portion B of FIG. 7A.

FIGS. 8A and 8B are graphs illustrating example frequency characteristics of the bulk acoustic wave resonator having the frame of a wide width, with FIG. 8B showing an enlarged portion C of FIG. 8A.

FIGS. 9A and 9B are graphs illustrating example frequency characteristics of the bulk acoustic wave resonator having the frame of a narrow width, with FIG. 9B showing an enlarged portion D of FIG. 9A.

FIG. 10A is a graph illustrating example frequency characteristics of a shunt resonator and a series resonator having the frame of a wide width. FIG. 10B is a graph illustrating example frequency characteristics of a bulk acoustic wave filter including the shunt resonator and the series resonator having the frame of a wide width.

FIGS. 11A is a graph illustrating example frequency characteristics of a shunt resonator and a series resonator having the frame of a narrow width. FIG. 11B is a graph illustrating example frequency characteristics of a bulk acoustic wave filter including the shunt resonator and the series resonator having the frame of a narrow width.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

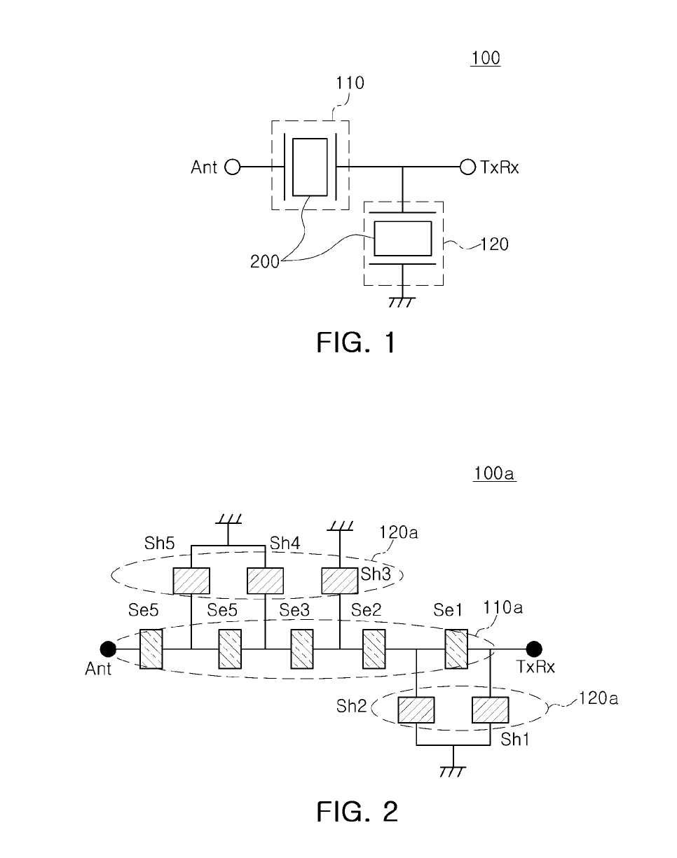

FIGS. 1 through 4 are diagrams illustrating examples of bulk acoustic wave filters.

Referring to FIG. 1, a bulk acoustic wave filter 100, according to an example, includes a first resonator part 110 and a second resonator part 120.

The bulk acoustic wave filter 100 may output a signal by differently adjusting a gain of an input signal depending on frequencies. That is, the bulk acoustic wave filter 100 may use bulk acoustic wave resonators 200 having variable impedance depending on frequencies.

For example, when impedance of series-connected resonators is lower than that of shunt-connected resonators, the bulk acoustic wave filter 100 may output a signal by slightly reducing a gain of an input signal. Alternatively, when impedance of series-connected resonators is higher than that of shunt-connected resonators, the bulk acoustic wave filter 100 may output a signal by significantly reducing a gain of an input signal.

The bulk acoustic wave resonators 200 may have significant variations in impedance depending on changes in frequency within a specific frequency range. The bulk acoustic wave filter 100 may filter a signal to output a filtered signal having a narrow bandwidth by using sharp changes in impedance of the resonators. For example, the bulk acoustic wave filter 100 may be included in a radio frequency (RF) device to which sharp filtering is applied.

The first resonator part 110 includes a bulk acoustic wave resonator connected between a signal port for transmitting and receiving a signal and a node connected to an antenna port. For example, the first resonator part 110 may include one or more resonators connected in series.

The second resonator part 120 includes a bulk acoustic wave resonator connected between the signal port and a ground. For example, the second resonator part 120 may include one or more resonators connected in shunt. In order for the bulk acoustic wave filter 100 to serve as a band-pass filter (BPF), a resonance frequency of the resonator included in the second resonator part 120 may be lower than that of the resonator included in the first resonator part 120.

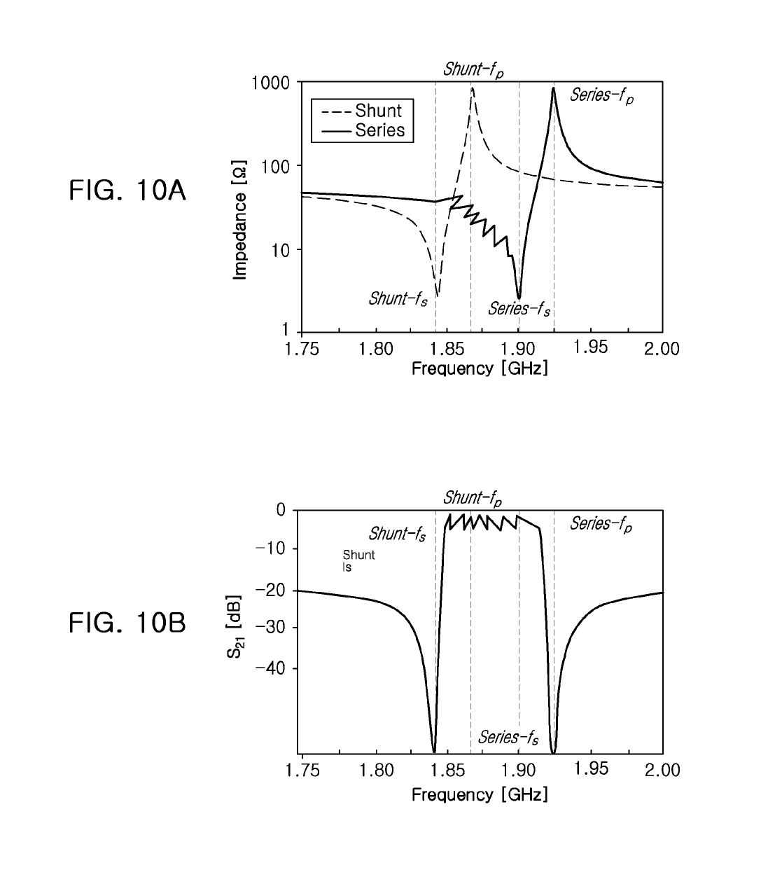

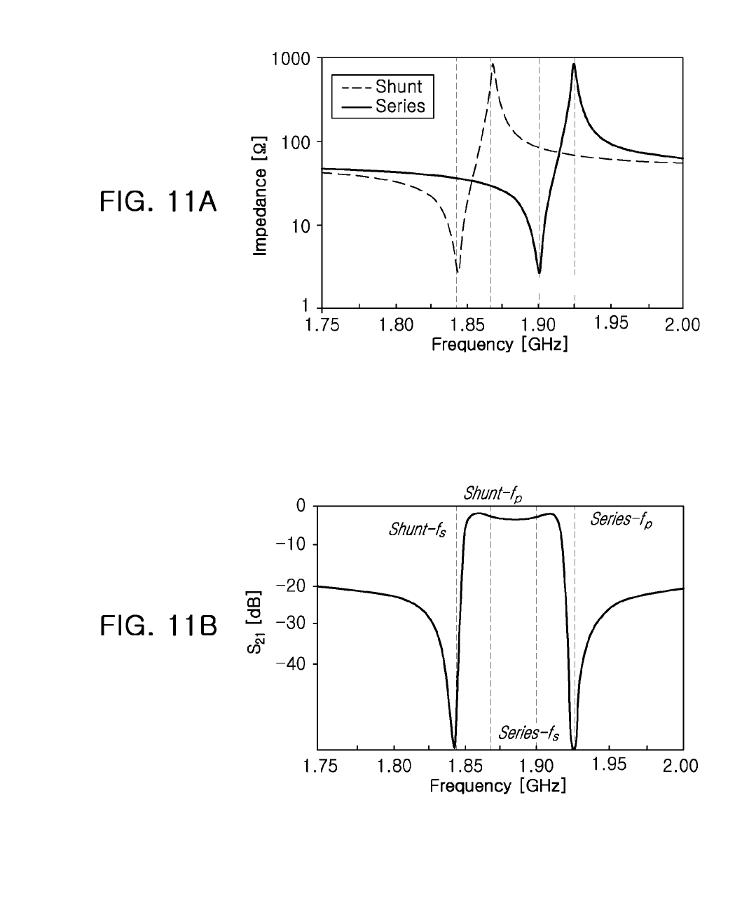

A quality factor (IF) value of the resonator included in the first resonator part 110 may be less than that of the resonator included in the second resonator part 120. For example, if the IF value of the bulk acoustic wave resonator is high, response characteristics for a signal having a frequency which is slightly lower than the resonance frequency of the bulk acoustic resonator may be unstable. In a case in which the IF value of the resonator included in the first resonator part 110 is high, a ripple may occur in a passband of the bulk acoustic wave filter 100. Thus, in a case in which the IF value of the resonator included in the first resonator part 110 is less than that of the resonator included in the second resonator part 120, the ripple occurring in the passband may be reduced without decreasing the IF value of the bulk acoustic wave filter 100. A detailed description of frequency characteristics of first resonator part 110, the second resonator part 120, and the bulk acoustic wave filter 100 will be provided below with reference to FIGS. 10 and 11.

Similarly, an electro-mechanical coupling coefficient (kt2) value of the bulk acoustic wave resonator included in the first resonator part 110 may be greater than that of the bulk acoustic wave resonator included in the second resonator part 120. As a result, the ripple occurring in the passband may be reduced without decreasing the IF value of the bulk acoustic wave filter 100.

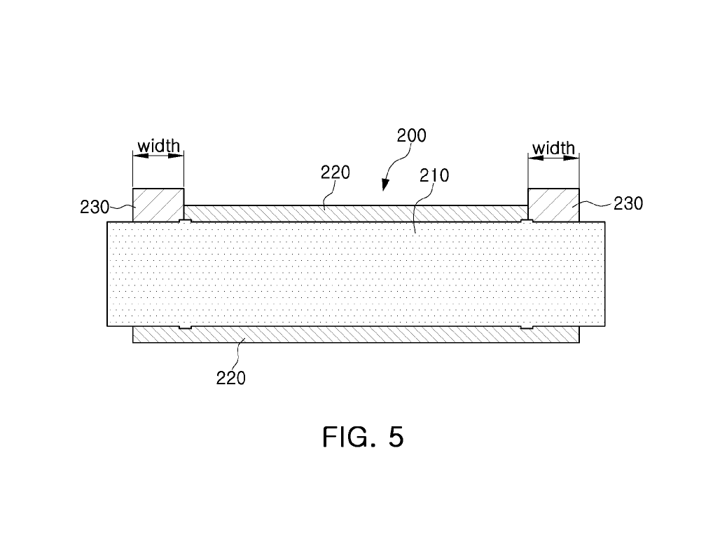

An example method of decreasing the IF value or increasing the kt2 value of the bulk acoustic wave filter 100 will be described below with reference to a bulk acoustic wave resonator 200 illustrated in FIG. 5.

Referring to FIG. 2, a bulk acoustic wave filter 100a, according to an example, includes a first resonator part 110a and a second resonator part 120a. The first resonator part 110a includes bulk acoustic wave resonators Se1-Se5, and the second resonator part 120a includes bulk acoustic wave resonators Sh1-Sh5. The bulk acoustic wave resonators Se1-Se5 included in the first resonator part 110a are connected in series with each other. The bulk acoustic wave resonators Sh1-Sh5 included in the second resonator part 120 are connected in parallel with each other.

However, other configurations of the bulk acoustic wave filter 100a are possible. For example, the first resonator part 110a and the second resonator part 120a may each include a greater or lesser number of bulk acoustic wave resonators than the number of resonators shown in FIG. 2. According to another example, first resonator part 110a may include only one bulk acoustic wave resonator, or the second resonator part 120a may include only one bulk acoustic wave resonator.

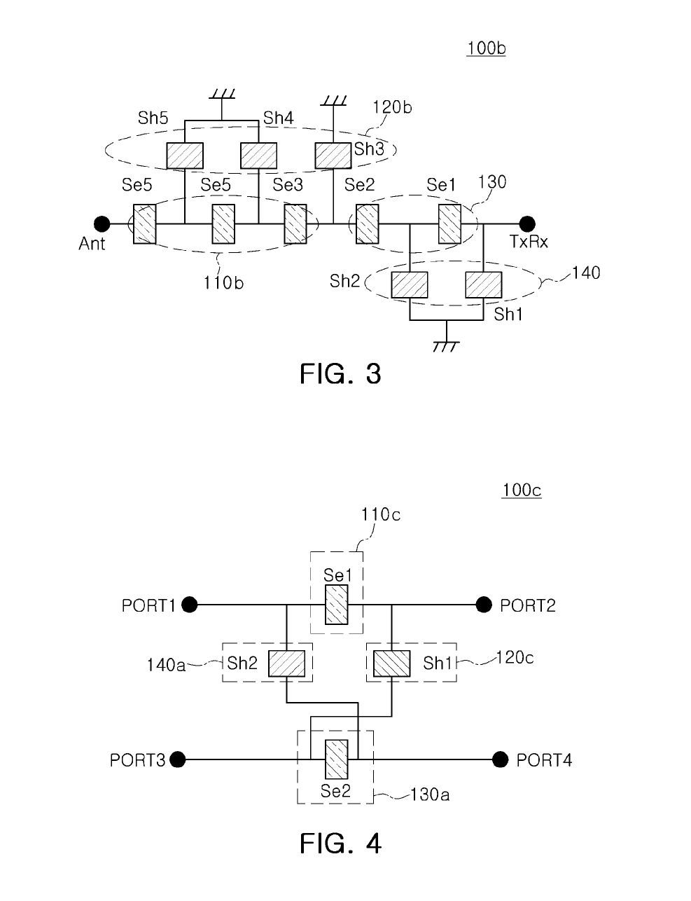

Referring to FIG. 3, a bulk acoustic wave filter 100b, according to an example, includes a first resonator part 110b, the second resonator part 120b, a third resonator part 130 and a fourth resonator part 140.

The first resonator part 110b includes bulk acoustic wave resonators Se3-Se5.

The second resonator part 120b includes bulk acoustic wave Sh3-Sh5.

The third resonator part 130 includes bulk acoustic wave resonators Se1 and Se2 connected between the second resonator part 120b and the signal port for transmitting and receiving a signal. For example, the bulk acoustic wave resonators Se1 and Se2 are connected in series and may perform a function similar to that of the first resonator part 110a of FIG. 2.

The fourth resonator part 140 includes bulk acoustic wave resonators Sh1 and Sh2 connected between the third resonator part 130 and the ground. For example, the bulk acoustic wave resonators Sh1 and Sh2 are connected in shunt and may perform a function similar to that of the second resonator part 120a of FIG. 2.

A IF value of at least one of the bulk acoustic wave resonators Se3-Se5 included in the first resonator part 110b and the bulk acoustic wave resonators Se1 and Se2 included in the third resonator part 130 may be less than that of the bulk acoustic wave resonators Sh3-Sh5 included in the second resonator part 120b and that of the bulk acoustic wave resonators Sh1 and Sh2 included in the fourth resonator part 140. That is, the IF value of all resonators Se1-Se5 connected in series is not less than that of all resonators Sh1-Sh5 connected in shunt. As a result, the ripple occurring in the passband may be further reduced without decreasing the IF value of the bulk acoustic wave filter 100.

Similarly, a kt2 value of at least one of the resonators Se3-Se5 included in the first resonator part 110b and the resonators Se1 and Se2 included in the third resonator part 130 may be greater than that of the resonators Sh3-Sh5 included in the second resonator part 120b and that of the resonators Sh1 and Sh2 included in the fourth resonator part 140. That is, the kt2 value of all resonators Se1-Se5 connected in series is not greater than that of all resonators Se1-Se5 connected in shunt. As a result, the ripple occurring in the passband may be further reduced without decreasing the IF value of the bulk acoustic wave filter 100b.

Referring to FIG. 4, a bulk acoustic wave filter 100c, according to an example, may be a lattice type filter. For example, the resonators connected in shunt may intersect each other.

A first resonator part 110c includes a bulk acoustic wave resonator Se1 connected between a first port PORT1 and a second port PORT2. For example, the first resonator part 110c may include resonators connected in series and may perform a function similar to that of the first resonator part 110a of FIG. 2.

A second resonator part 120c includes a bulk acoustic wave resonator Sh1 connected between the second port PORT2 and a third port PORT3. For example, the second resonator part 120c may include resonators connected in shunt and may perform a function similar to that of the second resonator part 120a of FIG. 2.

A third resonator part 130a includes a bulk acoustic wave resonator Se2 connected between the third port PORT3 and a fourth port PORT4. For example, the third resonator part 130a may include resonators connected in series and may perform a function similar to that of the third resonator part 130 of FIG. 3.

A fourth resonator part 140a includes a bulk acoustic wave resonator Sh2 connected between the fourth port PORT4 and the first port PORT1. For example, the fourth resonator part 140a may include resonators connected in shunt and may perform a function similar to that of the fourth resonator part 140 of FIG. 3.

FIG. 5 is a diagram illustrating a bulk acoustic wave resonator 200 included in the bulk acoustic wave filters 100-100c described above, according to an example.

Referring to FIG. 5, the bulk acoustic wave resonator 200includes a piezoelectric layer 210, electrodes 220, and a frame 230.

The bulk acoustic wave resonator 200 is operated by the plurality of electrodes 220 disposed on and below the piezoelectric layer 210. The bulk acoustic wave resonator 200 may be operated as a filter while the piezoelectric layer 210 is vibrated when a high frequency potential is applied to the electrodes 220. For example, the bulk acoustic wave resonator 200 may be suspended above a substrate through an air cavity in order to improve reflection characteristics of acoustic waves.

The piezoelectric layer 210 includes a piezoelectric material. The piezoelectric material is a material capable of converting dynamic energy into electrical energy.

The electrodes 220 are disposed on two opposing surfaces of the piezoelectric layer 210.

The frame 230 is disposed on one surface of the piezoelectric layer 210 and surrounds at least one of the electrodes 220. The frame 230 efficiently confines acoustic energy in the interior of the resonator by reflecting a lateral acoustic wave generated from the bulk acoustic wave resonator 200 to the interior of the bulk acoustic wave resonator 200. Thus, the quality factor (IF) of the bulk acoustic wave resonator 200 may be increased.

In addition, as a width of the frame 230 is increased, the frame 230 may more efficiently confine acoustic energy in the interior of the resonator 200. Thus, the IF of the bulk acoustic wave resonator 200 may be efficiently increased.

However, parasitic capacitance may be present between the frame 230 and the electrodes 220. The parasitic capacitance may reduce the electro-mechanical coupling coefficient (kt2) value of the bulk acoustic wave resonator 200. In addition, as the width of the frame 230 is increased, the parasitic capacitance may be increase. In a case in which the kt2 value of the bulk acoustic wave resonator 200 is reduced, a ripple may occur in the output of the bulk acoustic wave filter 100.

Thus, with respect to the examples provided in FIGS. 1-4, the width of the frame 230 included in at least one of the bulk acoustic wave resonators 200 included in the first resonator part 110, 110a, 110b or 110c may be narrower than that of the frame 230 included in at least one of the bulk acoustic wave resonators 200 included in the second resonator part 120, 120a, 120b or 120c. As a result, a quality factor (IF) value of the at least one resonator included in the first resonator parts 110, 110a, 110b and 110c may be less than that of the at least one resonator included in the second resonator part 120, 120a, 120b or 120c.

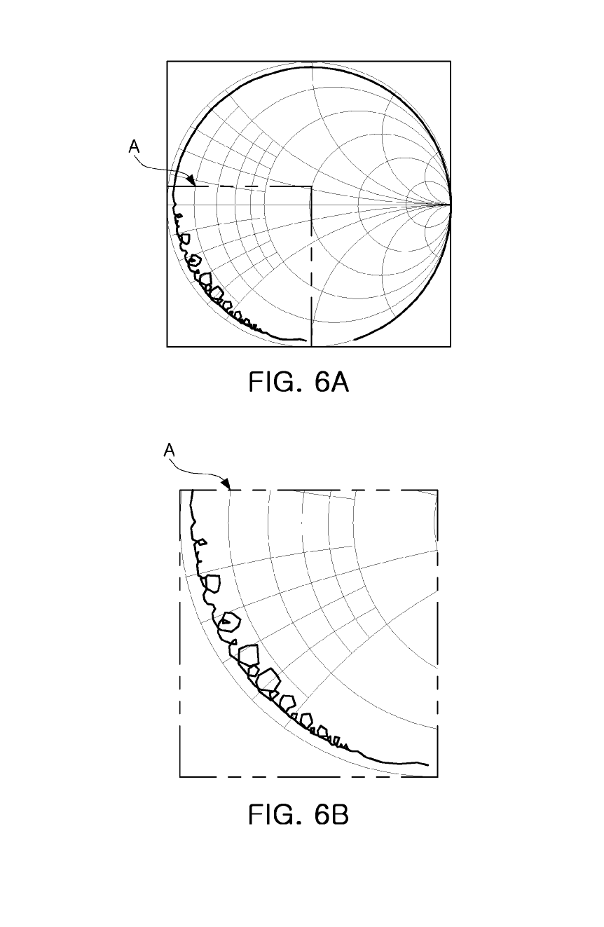

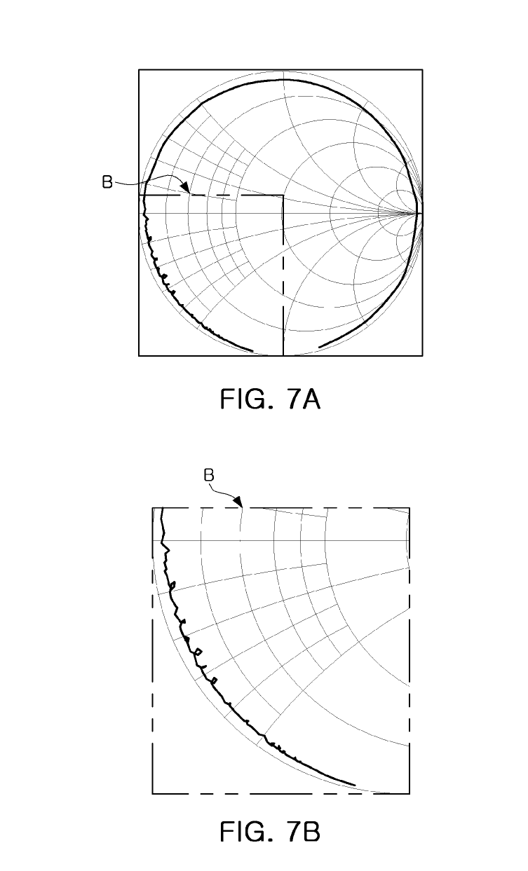

FIGS. 6A, 6B, 7A and 7B are Smith charts illustrating frequency characteristics of a bulk acoustic wave resonator 200 included in a bulk acoustic wave filter according to an example.

FIG. 6A illustrates frequency characteristics of the bulk acoustic wave resonator 200 having the frame 230 of a wide width. FIG. 7A illustrates frequency characteristics of the bulk acoustic wave resonator 200 having the frame 230 of a narrow width. FIGS. 6Band 7B illustrate enlarged graphs showing portions A and B of FIGS. 6A and 7A, respectively.

As the IF value of the bulk acoustic wave resonator 200 is increased, the size of a large circle (main resonance) on the Smith chart may be increased. In addition, as the kt2 value of the bulk acoustic wave resonator is increased, the size of small circles (low resonance) on the Smith chart may be reduced while spurious harmonic noise is reduced.

Referring to FIGS. 7A and 7B, it can be seen that since the size of the large circle on the Smith chart is reduced, the IF value is low, and since the size of the small circles on the Smith chart is reduced, the kt2 value is high.

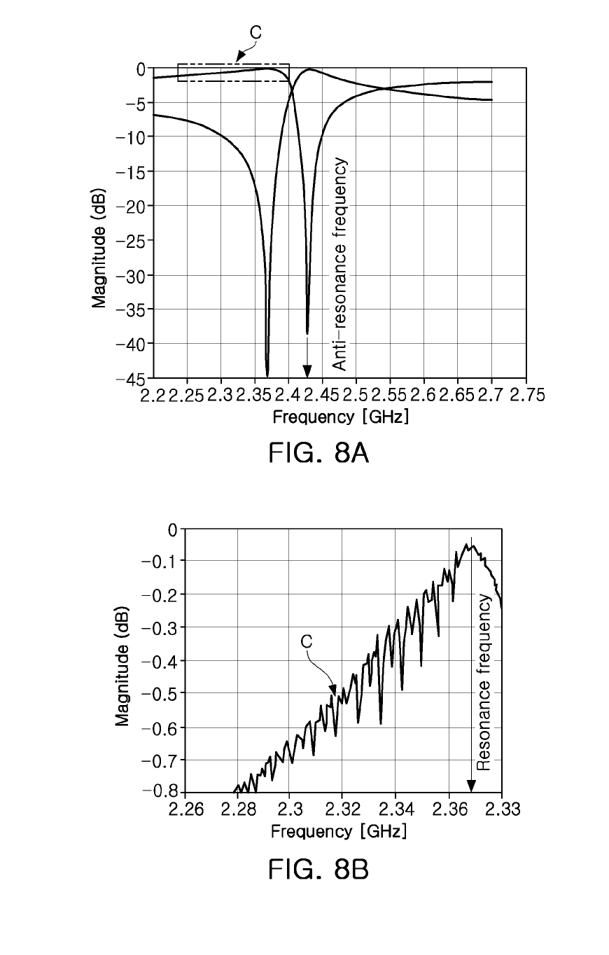

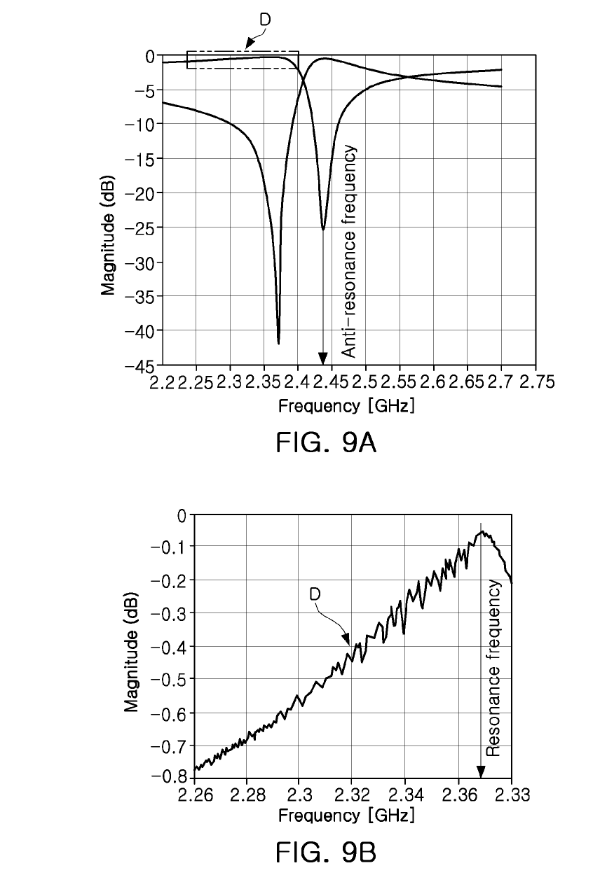

FIGS. 8A, 8B, 9A and 9B are graphs illustrating frequency characteristics of a bulk acoustic wave resonator 200 included in a bulk acoustic wave filter according to an example.

FIG. 8A illustrates frequency characteristics of the bulk acoustic wave resonator 200 having the frame 230 of a wide width. FIG. 9A illustrates frequency characteristics of the bulk acoustic wave resonator 200 having the frame 230 of a narrow width. FIGS. 8B and 9B illustrate enlarged graphs showing portions C and D of FIGS. 8A and 9B, respectively.

As a IF value of the bulk acoustic wave resonator 200 is increased, a rejection ratio at a resonance frequency may be increased. In addition, as a kt2 value of the bulk acoustic wave resonator is increased, a ripple may be reduced while spurious harmonic noise is reduced.

Referring to FIGS. 9A and 9B, it can be seen that since the rejection ratio at the resonance frequency is reduced, the IF value is low, and since the ripple is reduced, the kt2 value is high.

FIGS. 10A, 10B, 11 A and 11 B are graphs illustrating frequency characteristics of the bulk acoustic wave filter 100 according to an example.

FIG. 10A illustrates frequency characteristics of a shunt resonator and a series resonator having the frame 230 of a wide width. FIG. 11A illustrates frequency characteristics of a shunt resonator and a series resonator having the frame 230 of a narrow width. FIG. 10B illustrates frequency characteristics of the bulk acoustic wave filter 100 including the shunt resonator and the series resonator having the frame 230 of a wide width, while FIG. 11B illustrates frequency characteristics of the bulk acoustic wave filter 100 including the shunt resonator and the series resonator having the frame 230 of a narrow width.

Referring to FIG. 10B, in a case in which the frame 230 included in the resonator is relatively wide, a ripple may occur in the output of the bulk acoustic wave filter 100 at a frequency which is slightly lower than a resonance frequency. In a case in which the bulk acoustic wave filter 100 is a band-pass filter (BPF), the resonance frequency of the series resonator may be set to be slightly higher than that of the shunt resonator. Thus, the ripple may occur in the passband of the bulk acoustic wave filter 100. Thus, the ripple occurring in the passband of the bulk acoustic wave filter 100 may be reduced by narrowing the width of the frame 230 included in the series resonator, as shown in FIG. 11B.

In general, an increase in IF and a decrease in ripple of a bulk acoustic wave filter may have a conflicting relationship. However, the bulk acoustic wave filter 100, according to an example, may effectively reduce the ripple occurring in the passband, without decreasing IF. For example, the bulk acoustic wave filter 100 including the series resonator having the frame of the narrow width and the shunt resonator having the frame of the wide width may reduce the ripple without decreasing IF. As a result, a bandwidth of the bulk acoustic wave filter 100 may be expanded.

As set forth above, according to examples described herein, the ripple occurring in the output of the bulk acoustic wave filter may be reduced and the bandwidth may be expanded.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave filter comprising:
a first resonator part comprising one or more first bulk acoustic wave resonators connected between a signal port for transmitting or receiving a signal and a node connected to an antenna port; and
a second resonator part comprising one or more second bulk acoustic wave resonators connected between the signal port and a ground,
wherein a quality factor (IF) value of the one or more first bulk acoustic wave resonators is less than a IF value of the one or more second bulk acoustic wave resonators.

2. The bulk acoustic wave filter of claim 1, wherein:
the one or more first bulk acoustic wave resonators comprise a first plurality of bulk acoustic wave resonators connected in series with each other, and
the one or more second bulk acoustic wave resonators comprise a second plurality of bulk acoustic wave resonators connected in parallel with each other.

3. The bulk acoustic wave filter of claim 2, wherein
the first plurality of bulk acoustic wave resonators and the second plurality of bulk acoustic wave resonators each include:
a piezoelectric layer including a piezoelectric material;
electrodes disposed on opposing surfaces of the piezoelectric layer, and
a frame disposed on one of the opposing surfaces of the piezoelectric layer and surrounding at least one of the electrodes; and
a width of the frame included in at least one bulk acoustic resonator among the first plurality of bulk acoustic wave resonators is narrower than a width of the frame included in at least one bulk acoustic wave resonator among the second plurality of bulk acoustic wave resonators.

4. The bulk acoustic wave filter of claim 1, wherein:
each of the one or more first bulk acoustic wave resonators and each of the one or more second bulk acoustic wave resonators comprises
a piezoelectric layer including a piezoelectric material,
electrodes disposed on opposing surfaces of the piezoelectric layer, and
a frame disposed on one of the opposing surfaces of the piezoelectric layer and surrounding at least one of the electrodes; and
a width of the frame included in the at least one bulk acoustic wave resonator among the one or more first bulk acoustic wave resonators is narrower than a width of the frame included in the one or more second bulk acoustic wave resonators.

5. The bulk acoustic wave filter of claim 1, wherein an electro-mechanical coupling coefficient (kt2) value of the one or more first bulk acoustic wave resonators is greater than a kt2 value of the one or more second bulk acoustic wave resonators.

6. A bulk acoustic wave filter comprising:
a first resonator part comprising one or more first bulk acoustic wave resonators connected to a node connected to an antenna port;
a second resonator part comprising one or more second bulk acoustic wave resonators connected between the first resonator part and a ground;
a third resonator part comprising one or more third bulk acoustic wave resonators connected between the second resonator part and a signal port for transmitting or receiving a signal; and
a fourth resonator part comprising one or more fourth bulk acoustic wave resonators connected between the third resonator part and the ground,
wherein an electro-mechanical coupling coefficient (kt2) value of at least one bulk acoustic resonator, among the one or more first bulk acoustic wave resonators and the one or more third bulk acoustic wave resonators, is greater than a kt2 value of the one or more second bulk acoustic wave resonators and a kt2 value of the one or more fourth bulk acoustic wave resonators.

7. The bulk acoustic wave filter of claim 6, wherein:
at least one of the one or more first bulk acoustic wave resonators and the one or more third bulk acoustic wave resonators includes a first plurality of bulk acoustic wave resonators connected in series with each other, and
at least one of the one or more second bulk acoustic wave resonators and the one or more fourth bulk acoustic wave resonators includes a second plurality of bulk acoustic wave resonators connected in parallel with each other.

8. The bulk acoustic wave filter of claim 7, wherein:
the first plurality of bulk acoustic wave resonators and the second plurality of bulk acoustic wave resonators each include
a piezoelectric layer including a piezoelectric material,
electrodes disposed on opposing surfaces of the piezoelectric layer, and
a frame disposed on one of the opposing surfaces of the piezoelectric layer and surrounding at least one of the electrodes; and
a width of the frame included in at least one bulk acoustic wave resonator among the first plurality of bulk acoustic wave resonators is narrower than a width of the frame included in at least one bulk acoustic wave resonator among the second plurality of bulk acoustic wave resonators.

9. The bulk acoustic wave filter of claim 6, wherein:
each of the one or more first bulk acoustic wave resonators, the one or more second bulk acoustic wave resonators, the one or more third bulk acoustic wave resonators, and the one or more fourth bulk acoustic wave resonators comprises
a piezoelectric layer including a piezoelectric material,
electrodes disposed on opposing surfaces of the piezoelectric layer, and
a frame disposed on one of the opposing surfaces of the piezoelectric layer and surrounding at least one of the electrodes; and
a width of the frame included in at least one of the one or more first bulk acoustic wave resonators and the one or more third bulk acoustic wave resonators is narrower than a width of the frame included in the one or more second bulk acoustic wave resonators and a width of the frame included in the one or more fourth bulk acoustic wave resonators.

10. The bulk acoustic wave filter of claim 6, wherein a quality factor (IF) value of at least one bulk acoustic wave resonator among the one or more first bulk acoustic wave resonators and the one or more third bulk acoustic wave resonators is less than a IF value of the one or more second bulk acoustic wave resonators and a IF value of the one or more fourth bulk acoustic wave resonators.

11. A bulk acoustic wave filter, comprising:
first bulk acoustic wave resonators connected in series with each other; and
second bulk acoustic wave resonators connected in parallel with each other, and connected to the first bulk acoustic wave resonators,
wherein each of the first bulk acoustic wave resonators and each of the second bulk acoustic wave resonators comprises
a piezoelectric layer including a piezoelectric material,
electrodes disposed on opposing surfaces of the piezoelectric layer, and
a frame disposed on one of the opposing surfaces of the piezoelectric layer and surrounding at least one of the electrodes, and
wherein the frame of at least one first bulk acoustic wave resonator among the first bulk acoustic wave resonators has a width that is narrower than a width of a frame of at least one second bulk acoustic wave resonator among the second bulk acoustic wave resonators.

12. The bulk acoustic wave filter of claim 11, wherein the frame of the at least one first bulk acoustic wave resonator provides the at least one first bulk acoustic wave resonator with a quality factor (IF) value that is less than a IF value of the at least one second bulk acoustic wave resonator.
